(19) United States
(12) Patent Application Publication
(10) Pub. No.: US 2026/0223586 A1
(43) Pub. Date: Jul. 30, 2026

(54) DISPLAY PANEL AND MANUFACTURING METHOD THEREFOR, AND DISPLAY DEVICE

(71) Applicant: BOE Technology Group Co., Ltd., Beijing (CN)

(72) Inventors: Zhongyuan SUN, Beijing (CN); Jinxiang XUE, Beijing (CN); Weijie WANG, Beijing (CN); Che AN, Beijing (CN); Wenqi LIU, Beijing (CN); Chengyuan LUO, Beijing (CN); Zhiqiang JIAO, Beijing (CN); Junhan ZHU, Beijing (CN)

(21) Appl. No.: 19/145,924

(22) PCT Filed: Jun. 24, 2024
(86) PCT No.: PCT/CN2024/101074

§ 371 Date: Jul. 5, 2025

(30) Foreign Application Priority Data
Jun. 30, 2023 (CN) 202310797409.X

(51) Int. Cl. H10K 77/10; H10K 59/12; H10K 59/131; H10K 59/80; H10K 71/00

(52) U.S. Cl. CPC H10K 77/111; H10K 59/1201; H10K 59/131; H10K 59/8722; H10K 59/8731; H10K 71/851

(57) ABSTRACT

A display panel is provided. For island-shaped display regions included in a first stretchable substrate in the display panel, the first stretchable substrate and a display substrate are connected by a first adhesive layer, and a second stretchable substrate and the display substrate are connected by a second adhesive layer, so that the display substrate is fixed between the first stretchable substrate and the second stretchable substrate. For a stretchable region included in the first stretchable substrate in the display panel, no adhesive layer is provided to fix the display substrate.

The present disclosure is a U.S. national phase application based on PCT/CN2024/101074, filed on Jun. 24, 2024, which claims priority to Chinese Patent Application No. 202310797409.X, filed on Jun. 30, 2023, and entitled “DISPLAY PANEL AND MANUFACTURING METHOD THEREFOR, AND DISPLAY DEVICE”, both of which are incorporated by reference herein.

### TECHNICAL FIELD

The present disclosure relates to the field of display technologies, and in particular, relates to a display panel and a manufacturing method therefor, and a display device.

### BACKGROUND

Organic light-emitting diode (OLED) display panels have the advantages of self-luminescence, low driving voltage, and fast response. Compared with liquid crystal display panels, OLED display panels can be bent and have a wider range of applications. In addition, after several years of technological accumulation, the development of OLED display panels has gradually developed from the current bendable products to foldable products, and even stretchable products.

### SUMMARY

The present disclosure provides a display panel and a manufacturing method therefor, and a display device. The technical solutions are as follows:

In one aspect, a display panel is provided. The display panel includes:
a first stretchable substrate, wherein the first stretchable substrate includes a plurality of island-shaped display regions, a stretchable region connecting adjacent island-shaped display regions, and a hollow-out region between one of the island-shaped display regions and the stretchable region;
a display substrate, wherein the display substrate includes a plurality of display units disposed in the island-shaped display regions;
a first adhesive layer disposed between the display substrate and the first stretchable substrate, wherein an orthographic projection of the first adhesive layer on the first stretchable substrate is within orthographic projections of the display units on the first stretchable substrate; and
a second adhesive layer disposed on a side of the display substrate away from the first stretchable substrate, and a second stretchable substrate disposed on a side of the second adhesive layer away from the display substrate, wherein an orthographic projection of the second adhesive layer on the first stretchable substrate is within the orthographic projections of the display units on the first stretchable substrate.

In some embodiments, each of the display units includes a first flexible substrate, a display layer, and an encapsulation film layer that are stacked in sequence in a direction away from the first stretchable substrate; wherein
for each of the island-shaped display regions, the display substrate includes at least one display unit disposed in the island-shaped display region, and each of the display units includes a plurality of sub-pixels.

In some embodiments, the display substrate further includes a plurality of signal lines, wherein a portion of each of the signal lines is disposed in the island-shaped display region, and another portion is disposed in the stretchable region; and
the portion of each of the signal lines located in the island-shaped display region is connected to the display layer of the display unit, and the signal line is configured to transmit a driving signal provided by a driver circuit.

In some embodiments, the display substrate further includes a second flexible substrate, a first flexible film layer, and a second flexible film layer that are disposed in the stretchable region and stacked in sequence in the direction away from the first stretchable substrate; wherein
the portion of each of the signal lines located in the stretchable region is disposed between the first flexible film layer and the second flexible film layer.

In some embodiments, a side of the first flexible substrate close to the first stretchable substrate is provided with one or more first groove structures; wherein
a portion of the first adhesive layer is disposed in each of the first groove structures, a portion of a surface of the first adhesive layer close to the first flexible substrate is adhered to an inner wall of each of the first groove structures, and a surface of the first adhesive layer close to the first stretchable substrate is adhered to the first stretchable substrate.

In some embodiments, the side of the first flexible substrate close to the first stretchable substrate includes a first region and a second region, the first region being closer to a connection between the island-shaped display region and the stretchable region than the second region; wherein
in the case that the side of the first flexible substrate close to the first stretchable substrate is provided with a plurality of first groove structures, an arrangement density of the first groove structures in the first region is greater than an arrangement density of the first groove structures in the second region.

In some embodiments, a shape of an orthographic projection of each of the first groove structures on the first stretchable substrate is a circle, an ellipse, a square, a regular hexagon, or a rhombus.

In some embodiments, in the case that the side of the first flexible substrate close to the first stretchable substrate is provided with a plurality of first groove structures, shapes of orthographic projections of the plurality of first groove structures on the first stretchable substrate are the same.

In some embodiments, in the case that the side of the first flexible substrate close to the first stretchable substrate is provided with a plurality of first groove structures, center points of orthographic projections of the plurality of first groove structures on the first stretchable substrate constitute a centrally symmetric figure, and a symcenter of the centrally symmetric figure is a center of the island-shaped display region.

In some embodiments, a depth of the first groove structure is 10% to 60% of a thickness of the first flexible substrate.

In some embodiments, the plurality of island-shaped display regions are arranged in an array in a first direction and a second direction; a shape of an orthographic projection of each of the first groove structures on a reference plane is one of a trapezoid, a semicircle, a semi-ellipse, and a T-shape; wherein
the reference plane is perpendicular to a supporting surface of the first stretchable substrate, and the reference plane is parallel to the first direction or the second direction.

In some embodiments, a side of the encapsulation film layer away from the first stretchable substrate is provided with one or more second groove structures; wherein
a portion of the second adhesive layer is disposed in the second groove structures, a portion of a surface of the second adhesive layer close to the first flexible substrate is adhered to an inner wall of the second groove structure, and a surface of the second adhesive layer close to the second stretchable substrate is adhered to the second stretchable substrate.

In some embodiments, the encapsulation film layer includes a first encapsulation layer, a second encapsulation layer, and a third encapsulation layer that are stacked in sequence in a direction away from the first stretchable substrate, wherein materials of the first encapsulation layer and the third encapsulation layer are inorganic materials, and a material of the second encapsulation layer is an organic material; and
the one or more second groove structures are disposed on a surface of the third encapsulation layer away from the first stretchable substrate; a distance between a surface of the second groove structure close to the first stretchable substrate and a surface of the third encapsulation layer close to the first stretchable substrate is greater than or equal to 600 nanometers.

In some embodiments, the display panel further includes a fixed film layer; wherein
the fixed film layer is disposed in the island-shaped display regions and between the first adhesive layer and the first stretchable substrate, and the first adhesive layer is configured to connect the fixed film layer and the first flexible substrate.

In some embodiments, in the case that a side of the first flexible substrate close to the first stretchable substrate is provided with one or more first groove structures, the fixed film layer includes a fixed layer, and one or more protruding structures disposed on a side of the fixed layer away from the first stretchable substrate and corresponding to the one or more first groove structures; and
an orthographic projection of each of the protruding structures on the first stretchable substrate is within an orthographic projection of a corresponding first groove structure on the first stretchable substrate.

In some embodiments, a height of each of the protruding structures is less than a depth of the corresponding first groove structure; and a thickness of the fixed layer is greater than or equal to 1 micron.

In some embodiments, the display layer includes a barrier layer, a buffer layer, an active layer, a gate insulating layer, a gate layer, an interlayer dielectric layer, a source-drain electrode layer, a planarization layer, an anode layer, a pixel defining layer, a light-emitting layer, and a cathode layer; wherein
the active layer includes an active pattern, wherein the active pattern includes a source region, a drain region, and a channel region;
the source-drain electrode layer includes a source electrode and a drain electrode, wherein the source electrode is connected to the source region through a first via hole in the interlayer dielectric layer and the gate insulating layer, and the drain electrode is connected to the drain region through a second via hole in the interlayer dielectric layer and the gate insulating layer; and
the gate layer includes a gate pattern, and the channel region is an overlapping region of an orthographic projection of the gate pattern on the first stretchable substrate and an orthographic projection of the active pattern on the first stretchable substrate.

In some embodiments, a plurality of signal lines in the display substrate are disposed in the source-drain electrode layer; and a second flexible film layer in the display substrate and the planarization layer are disposed in the same layer.

In another aspect, a method for manufacturing a display panel is provided. The method includes:
forming a display substrate on a glass substrate, wherein the display substrate includes a plurality of display units;
forming a temporary adhesive material and a protective film on a side of the display substrate away from the glass base;
removing the glass substrate, and adhering a first stretchable substrate to a side of the display substrate away from the protective film using a first adhesive layer; and
removing the temporary adhesive material and the protective film, and adhering the second stretchable substrate to a side of the display substrate away from the first stretchable substrate using a second adhesive layer;
wherein the first stretchable substrate includes a plurality of island-shaped display regions, a stretchable region connecting adjacent island-shaped display regions, and a hollow-out region between one of the island-shaped display regions and the stretchable region; a plurality of display units disposed in the island-shaped display regions; an orthographic projection of the first adhesive layer on the first stretchable substrate is within orthographic projections of the display units on the first stretchable substrate, and an orthographic projection of the second adhesive layer on the first stretchable substrate is within the orthographic projections of the display units on the first stretchable substrate.

In some embodiments, the forming the display substrate on the glass substrate includes:
forming one or more protrusions on the glass substrate, and forming a first flexible substrate film, a display film, and an encapsulation film on a side of the protrusions away from the glass substrate; and
obtaining a first flexible substrate, a display layer, and an encapsulation film layer disposed in the island-shaped display regions, and obtaining a second flexible substrate, a first flexible film layer, and a second flexible film layer disposed in the stretchable region by etching the first flexible substrate film, the display film, and the encapsulation film to remove the first flexible substrate film, the display film, and the encapsulation film disposed in the hollow-out region; and
the removing the glass substrate, and adhering the first stretchable substrate to the side of the display substrate away from the protective film using the first adhesive layer includes:
removing the glass substrate and the protrusions on the glass substrate, so that a side of the first flexible substrate away from the display layer is provided with one or more first groove structures, and adhering the first stretchable substrate to a side of the display substrate away from the protective film using a first adhesive layer, wherein a portion of the first adhesive layer is disposed in the first groove structures, a portion of a surface of the first adhesive layer close to the first flexible substrate is adhered to an inner wall of the first groove structures, and a surface of the first adhesive layer close to the first stretchable substrate is adhered to the first stretchable substrate.

In yet another aspect, a display device is provided. The display device includes a power supply component and the display panel as described in the above aspect; wherein
the power supply component is connected to the display panel, and is configured to supply power to the display panel.

### BRIEF DESCRIPTION OF DRAWINGS

To describe the technical solutions in the embodiments of the present disclosure more clearly, the following briefly describes the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a partial cross-sectional schematic diagram of a display panel according to some embodiments of the present disclosure;

FIG. 2 is a partial top view of a first stretchable substrate according to some embodiments of the present disclosure;

FIG. 3 is a partial top view of a display panel according to some embodiments of the present disclosure;

FIG. 4 is a partial schematic diagram of a display panel when stretched according to some embodiments of the present disclosure;

FIG. 5 is a partial cross-sectional schematic diagram of another display panel according to some embodiments of the present disclosure;

FIG. 6 is a partial top view of another display panel according to some embodiments of the present disclosure;

FIG. 7 is a top view of a first flexible substrate according to some embodiments of the present disclosure;

FIG. 8 is a top view of another first flexible substrate according to some embodiments of the present disclosure;

FIG. 9 is a top view of yet another first flexible substrate according to some embodiments of the present disclosure;

FIG. 10 is a top view of still another first flexible substrate according to some embodiments of the present disclosure;

FIG. 11 is a top view of still another first flexible substrate according to some embodiments of the present disclosure;

FIG. 12 is a schematic diagram of a first adhesive layer in the case that a first groove structure is not provided on a first flexible substrate according to some embodiments of the present disclosure;

FIG. 13 is a schematic diagram of a first adhesive layer in the case that a first groove structure is provided on a first flexible substrate according to some embodiments of the present disclosure;

FIG. 14 is a top view of still another first flexible substrate according to some embodiments of the present disclosure;

FIG. 15 is a top view of a first groove structure having different numbers of first grooves disposed in four regions of a first flexible substrate according to some embodiments of the present disclosure;

FIG. 16 is a top view of a first groove structure having different shapes arranged in four regions of a first flexible substrate according to some embodiments of the present disclosure;

FIG. 17 is a top view of still another first flexible substrate according to some embodiments of the present disclosure;

FIG. 18 is a partial cross-sectional view of a display unit according to some embodiments of the present disclosure;

FIG. 19 is a partial cross-sectional view of another display unit according to some embodiments of the present disclosure;

FIG. 20 is a partial cross-sectional view of yet another display unit according to some embodiments of the present disclosure;

FIG. 21 is a partial cross-sectional view of still another display unit according to some embodiments of the present disclosure;

FIG. 22 is a partial cross-sectional view of still another display unit according to some embodiments of the present disclosure;

FIG. 23 is a partial cross-sectional view of still another display panel according to some embodiments of the present disclosure;

FIG. 24 is a partial cross-sectional view of still another display panel according to some embodiments of the present disclosure;

FIG. 25 is a flowchart of a method for manufacturing a display panel according to some embodiments of the present disclosure;

FIG. 26 is a flowchart of a method for forming a display substrate according to some embodiments of the present disclosure;

FIG. 27 is a schematic diagram of forming a protrusion on a glass substrate according to some embodiments of the present disclosure;

FIG. 28 is a schematic diagram of forming a flexible substrate film according to some embodiments of the present disclosure;

FIG. 29 is a schematic diagram of forming a hollow-out region according to some embodiments of the present disclosure;

FIG. 30 is a schematic diagram of forming a temporary adhesive material and a protective film according to some embodiments of the present disclosure;

FIG. 31 is a schematic diagram of adhering a first stretchable substrate to a side of a display substrate away from a protective film according to some embodiments of the present disclosure;

FIG. 32 is a schematic diagram of adhering a second stretchable substrate to a side of a display substrate away from a first stretchable substrate according to some embodiments of the present disclosure; and

FIG. 33 is a schematic structural diagram of a display device according to some embodiments of the present disclosure.

### DETAILED DESCRIPTION

To make the objective, technical solutions, and advantages of the present disclosure clearer, embodiments of the present disclosure will be described in further detail below in conjunction with the accompanying drawings.

In some embodiments, an organic light-emitting diode (OLED) display panel includes a plurality of island-shaped display regions, and a stretchable region located between adjacent island-shaped display regions, and the stretchable region can withstand a certain deformation to achieve the stretching of the entire display panel. The two ends of the stretchable region are respectively connected to the two adjacent island-shaped display regions, and the region other than the island-shaped display region and the stretchable region in the OLED display panel is a hollow-out region. Usually, various signal lines need to be laid on the stretchable region, such that the signal lines are connected to the pixel units of different island-shaped display regions to achieve signal transmission.

However, the OLED display panel cannot be deformed in a direction perpendicular to the display panel, resulting in poor flexibility in use.

The OLED display panels have a series of advantages such as an all-solid-state structure, high brightness, full viewing angle, fast response speed, wide operating temperature range, and flexible display. At the same time, compared with liquid crystal display panels, OLED display panels can be bent and have a wider range of applications. For example, in the field of flexible display, OLED display panels can be curled and folded and thus have extremely broad prospects in the field of portable products or wearable products. After several years of technological accumulation, OLED display panels have gradually developed from bendable product forms to foldable products, and even stretchable products. At present, the stretchable display panel includes a rigid display region and an elastic wire region for connecting the rigid display region. The rigid display region does not withstand tensile deformation, and the elastic wire region can withstand a certain deformation to achieve the stretching of the entire display device.

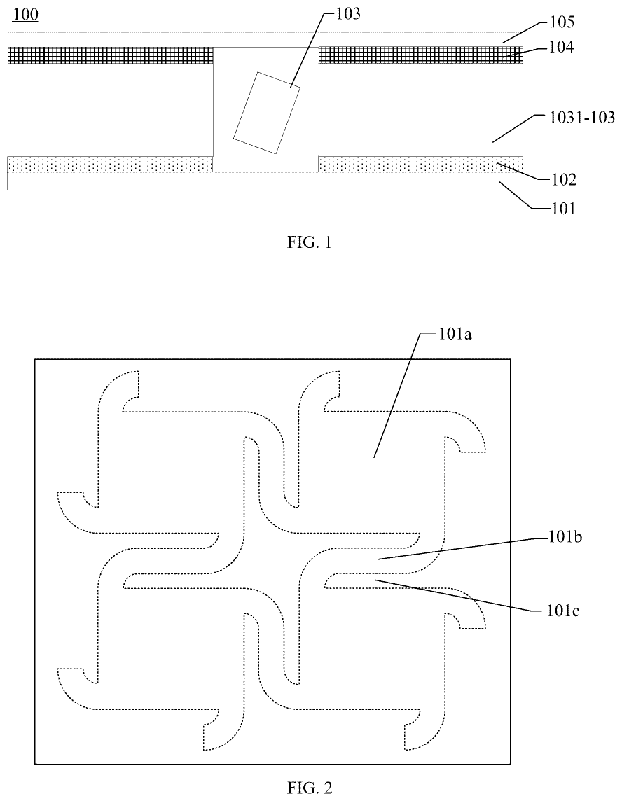

FIG. 1 is a schematic diagram of a display panel according to some embodiments of the present disclosure. Referring to FIG. 1, the display panel 100 includes: a first stretchable substrate 101, a first adhesive layer 102, a display substrate 103, a second adhesive layer 104, and a second stretchable substrate 105.

FIG. 2 is a partial top view of a first stretchable substrate according to some embodiments of the present disclosure. Referring to FIG. 2, the first stretchable substrate 101 includes a plurality of island-shaped display regions 101a, a stretchable region 101b connecting adjacent island-shaped display regions 101a, and a hollow-out region 101c between the island-shaped display region 101a and the stretchable region 101b. The island-shaped display region 101a may also be referred to as a display island. The plurality of island-shaped display regions 101a are used to represent a plurality of independently set regions, each of which may be used to arrange a display unit to achieve display.

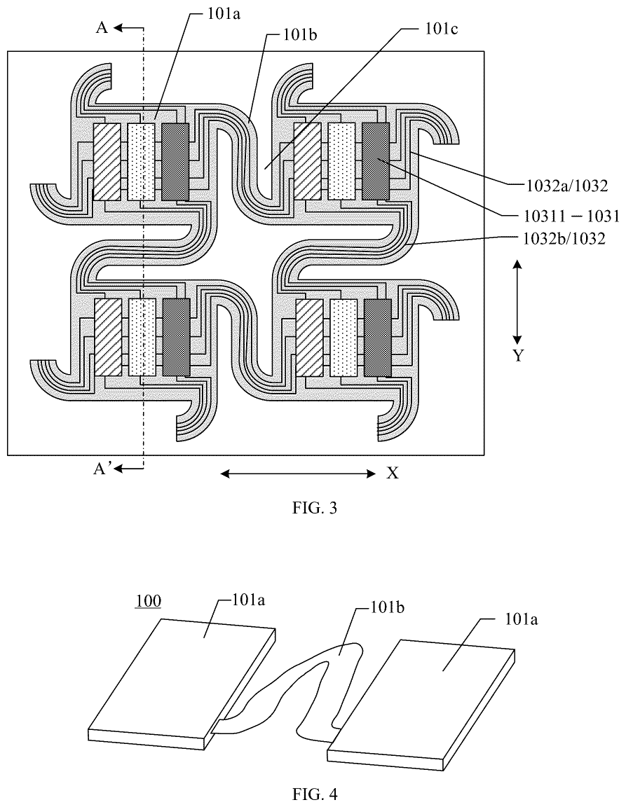

FIG. 3 is a partial top view of a display panel according to some embodiments of the present disclosure. Referring to FIG. 3, the display substrate 103 includes a plurality of display units 1031, and the display units 1031 are disposed in the island-shaped display regions 101a. Each display unit 1031 includes a plurality of sub-pixels 10311. For example, for each island-shaped display region 101a shown in FIG. 3, the display substrate 103 includes one display unit 1031 disposed in the island-shaped display region 101a. Each display unit 1031 includes three sub-pixels 10311.

Referring to FIG. 1, the first adhesive layer 102 is disposed between the display substrate 103 and the first stretchable substrate 101. The first adhesive layer 102 is used to adhere the display substrate 103 to the first stretchable substrate 101, such that the display substrate 103 is fixed on the first stretchable substrate 101.

An orthographic projection of the first adhesive layer 102 on the first stretchable substrate 101 is within orthographic projections of the display units 1031 on the first stretchable substrate 101. That is, the first adhesive layer 102 is only provided in the island-shaped display region 101a, and is used to adhere the portion of the display substrate 103 disposed in the island-shaped display region 101a and the island-shaped display region 101a of the first stretchable substrate 101. In addition, the first adhesive layer 102 does not need to be provided in the stretchable region 101b, and the portion of the display substrate 103 disposed in the stretchable region 101b does not need to be adhered to the stretchable region 101b of the first stretchable substrate 101, and the portion of the display substrate 103 disposed in the stretchable region 101b only needs to be placed on the first stretchable substrate 101.

The second adhesive layer 104 is disposed on a side of the display substrate 103 away from the first stretchable substrate 101, and the second stretchable substrate 105 is disposed on a side of the second adhesive layer 104 away from the display substrate 103. That is, the second adhesive layer 104 is disposed between the display substrate 103 and the second stretchable substrate 105, and is used to adhere the display substrate 103 to the second stretchable substrate 105, such that the display substrate 103 is fixed between the first stretchable substrate 101 and the second stretchable substrate 105.

An orthographic projection of the second adhesive layer 104 on the first stretchable substrate 101 is within the orthographic projections of the display units 1031 on the first stretchable substrate 101. That is, the second adhesive layer 104 is only provided in the island-shaped display region 101a, and is used to adhere the portion of the display substrate 103 disposed in the island-shaped display region 101a and the portion of the second stretchable substrate 105 disposed in the island-shaped display region 101a. In addition, the second adhesive layer 104 does not need to be provided in the stretchable region 101b, and the portion of the display substrate 103 disposed in the stretchable region 101b does not need to be adhered to the portion of the second stretching substrate disposed in the stretchable region 101b.

In the embodiments of the present disclosure, in the island-shaped display region 101a, the display substrate 103 is fixed between two stretchable substrates by the first adhesive layer 102 and the second adhesive layer 104. And no adhesive layer is arranged in the stretchable region 101b for fixing. Referring to FIG. 4, taking the stretchable region as a U-shaped region as an example, since the display panel 100 is not fixed by the adhesive in a vertical direction (a third direction Z) perpendicular to the supporting surface of the stretchable substrate, after the display panel 100 is subjected to the stretching force, the portion of the display panel 100 located in the stretchable region 101b can generate strain in the vertical direction. In addition, the portion of the display panel 100 located in the stretchable region 101b can also be stretched in various directions (such as a first direction X and a second direction Y perpendicular to each other) on the surface of the first stretchable substrate 101. That is, the deformation flexibility of the display panel 100 is high, which increases the stretching amount of the display panel 100. The plurality of island-shaped display regions 101a can be arranged in an array in the first direction X and the second direction Y.

In summary, the embodiments of the present disclosure provide a display panel. For island-shaped display regions included in a first stretchable substrate, the first stretchable substrate and a display substrate are adhered by a first adhesive layer, and a second stretchable substrate and the display substrate are adhered by a second adhesive layer, the display substrate can be fixed between the first stretchable substrate and the second stretchable substrate. For the stretchable region included in the first stretchable substrate in the display panel, no adhesive layer is provided to fix the display substrate. Thus, after the display panel is subjected to a stretching force, the portion of the display panel located in the stretchable region can be stretched not only in various directions on the surface where the first stretchable substrate is located, but also in a direction perpendicular to the first stretchable substrate. That is, the deformation flexibility of the display panel is high, which increases the stretching amount of the display panel.

Referring to FIG. 3, the shape of the stretchable region 101b may be an S-shape. Alternatively, the shape of the stretchable region 101b may be other shapes, such as a U-shape, a V-shape, and a Z-shape. The embodiments of the present disclosure do not limit the shape of the stretchable region 101b, and it is only necessary that the stretchable region 101b can connect the adjacent island-shaped display regions 101a.

Optionally, the material of the first adhesive layer 102 and the second adhesive layer 104 may be an optically clear adhesive (OCA).

Optionally, the materials of the first stretchable substrate 101 and the second stretchable substrate 105 may be one of highly elastic materials such as polydimethylsiloxane (PDMS), styrene block copolymer (SEBS), aliphatic-aromatic random copolyester (Ecoflex) and rubber.

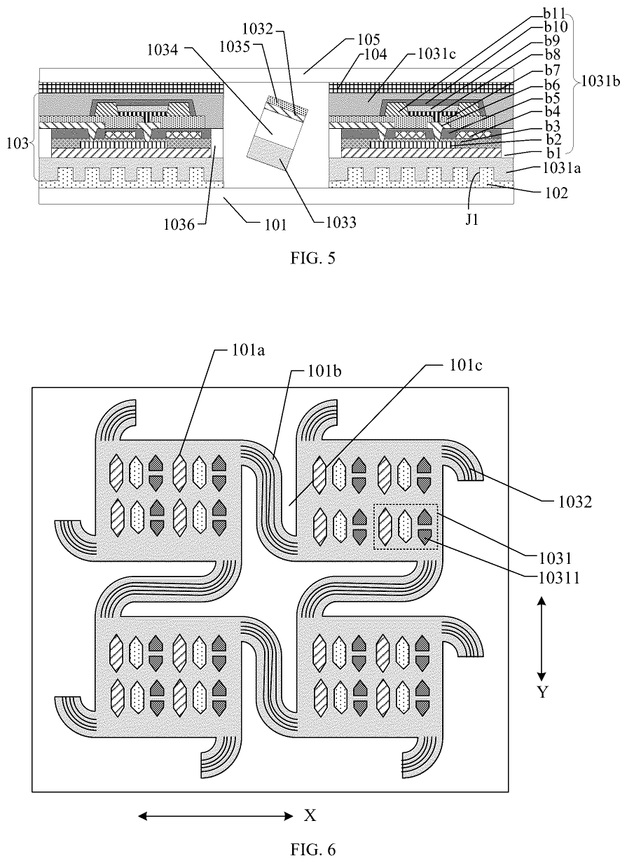

FIG. 5 is a partial cross-sectional view of another display panel according to some embodiments of the present disclosure. Moreover, FIG. 5 is also a cross-sectional view of FIG. 3 along the AA′ direction. Referring to FIG. 5, the display unit 1031 includes a first flexible substrate 1031a, a display layer 1031b, and an encapsulation film layer (thin film encapsulation, TFE) layer 1031c that are stacked in sequence in a direction away from the first stretchable substrate 101. Since the display unit 1031 is located in the island-shaped display region 101a, the first flexible substrate 1031a, the display layer 1031b, and the encapsulation film layer 1031c included in the display unit 1031 are disposed in the island-shaped display region 101a. Optionally, the material of the first flexible substrate 1031a may be a flexible material, such as polyimide (PI) or polyethylene terephthalate (PET).

Referring to FIG. 3, for each island-shaped display region 101a, the display substrate 103 includes at least one display unit 1031 located in the island-shaped display region 101a, and each display unit 1031 includes a plurality of sub-pixels. For example, in FIG. 3, in each island-shaped display region 101a, the display substrate 103 includes one display unit 1031 located in the island-shaped display region 101a. Each display unit 1031 includes three sub-pixels, which are respectively a red (R) sub-pixel, a green (G) sub-pixel, and a blue (B) sub-pixel. For example, in FIG. 6, in each island-shaped display region 101a, the display substrate 103 includes four display units 1031 located in the island-shaped display region 101a. Each display unit 1031 includes four sub-pixels, which are respectively a red sub-pixel, a blue sub-pixel, and two green sub-pixels.

Referring to FIG. 3 and FIG. 6, it can be seen that the display substrate 103 also includes a plurality of signal lines 1032. A portion of each signal line 1032 is disposed in the island-shaped display region 101a, and another portion is disposed in the stretchable region 101b. The portion of the signal line 1032 located in the island-shaped display region 101a is connected to the display layer 1031b of the display unit 1031, and the portion of the signal line 1032 located in the stretchable region 101b is used to transmit a driving signal provided by the driver circuit. To facilitate drawing the display units 1031 in FIG. 6, the portion of the signal line 1032 located in the island-shaped display region 101a is not drawn.

Referring to FIG. 3, the plurality of signal lines 1032 include a plurality of first-type signal lines 1032a and a plurality of second-type signal lines 1032b. The plurality of first-type signal lines 1032a are used to connect the display layers 1031b of the display units 1031 in the island-shaped display regions 101a arranged in the first direction X, thereby transmitting driving signals to the display units 1031 in the island-shaped display regions 101a arranged in the first direction X. The plurality of second-type signal lines 1032b are used to connect the display layers 1031b of the display units 1031 in the island-shaped display regions 101a arranged in the second direction Y, thereby transmitting driving signals to the display units 1031 in the island-shaped display regions 101a arranged in the second direction Y.

The plurality of first-type signal lines 1032a may include a gate signal line (gate), a reset signal line (reset), a reset power line (Vinit), and a light-emitting control signal line (EM), etc. The plurality of second-type signal lines 1032b may include a data signal line (data), a positive power supply line (VDD), and a negative power supply line (VSS), etc.

FIG. 3 schematically shows only four first-type signal lines 1032a and four second-type signal lines 1032b. In fact, the number of the first-type signal lines 1032a and the number of the second-type signal lines 1032b can be determined according to the actual design of the driver circuit layer included in the display layer 1031b of the display unit 1031.

Referring to FIG. 5, the display substrate 103 also includes a second flexible substrate 1033, a first flexible film layer 1034, and a second flexible film layer 1035 that are disposed in the stretchable region 101b and stacked in sequence in the direction away from the first stretchable substrate 101. The second flexible substrate 1033 and the first flexible substrate 1031a may be disposed in the same layer, that is, the second flexible substrate 1033 and the first flexible substrate 1031a may be made of the same material and manufactured based on a one-time patterning process. For example, the material of the second flexible substrate 1033 is PI or PET.

The portion of the signal line 1032 located in the stretchable region 101b is disposed between the first flexible film layer 1034 and the second flexible film layer 1035. That is, the signal line 1032 can be protected by the first flexible film layer 1034 and the second flexible film layer 1035. In addition, since the stretching effect of the flexible film layer is better than that of the rigid film layer, the film layers included in the stretchable region 101b of the display substrate 103 are all arranged as flexible film layers, which can improve the stretching effect of the stretchable region 101b.

Referring to FIG. 5, a side of the first flexible substrate 1031a close to the first stretchable substrate 101 is provided with one or more first groove structures J1. A portion of the first adhesive layer 102 is disposed in the first groove structures J1, a portion of the surface of the first adhesive layer 102 close to the first flexible substrate 1031a is adhered to an inner wall of the first groove structure J1, and a surface of the first adhesive layer 102 close to the first stretchable substrate 101 is adhered to the first stretchable substrate 101.

By providing the first groove structures J1 on the first flexible substrate 1031a, the contact area between the first flexible substrate 1031a and the first adhesive layer 102 can be increased, thereby increasing the stability of the display unit 1031 fixed on the first stretchable substrate 101, and significantly reducing the deformation force on the display unit 1031 during the stretching process.

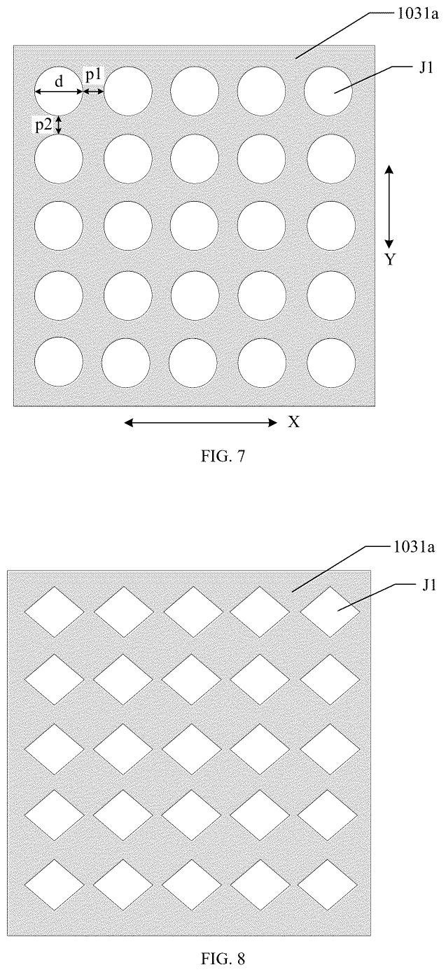

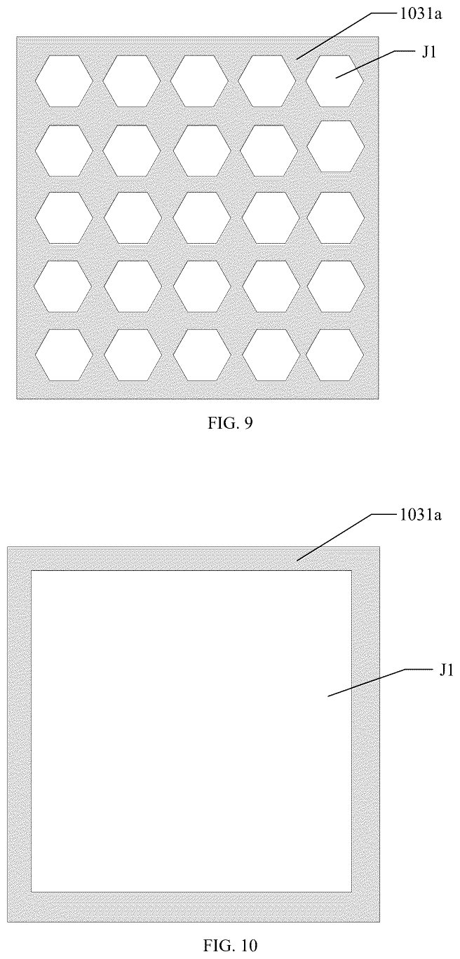

Optionally, a shape of an orthographic projection of each first groove structure J1 on the first stretchable substrate 101 is a circle, an ellipse, a square, a regular hexagon, or a rhombus. For example, in FIG. 7, the number of the first groove structures J1 is multiple, and the shape of the orthographic projection of the first groove structure J1 on the first stretchable substrate 101 is a circle. In FIG. 8, the number of the first groove structures J1 is multiple, and the shape of the orthographic projection of the first groove structure J1 on the first stretchable substrate 101 is a regular hexagon. In FIG. 9, the number of the first groove structures J1 is multiple, and the shape of the orthographic projection of the first groove structure J1 on the first stretchable substrate 101 is a rhombus. In FIG. 10, the number of the first groove structure J1 is one, and the shape of the orthographic projection of the first groove structure J1 on the first stretchable substrate 101 is a square.

Taking the shape of the orthographic projection of the first groove structure J1 on the first stretchable substrate 101 in FIG. 7 as a circle as an example, the diameter d of the circle can range from 60 nanometers (nm) to 200 micrometers (μm). The distance p between two adjacent circles can range from 60 nm to 10 μm. In addition, the distance p1 between two adjacent circles in the first direction X can be equal to or different from the distance p2 between two adjacent circles in the second direction Y, which is not limited in the embodiments of the present disclosure.

In the embodiments of the present disclosure, for each island-shaped display region 101a, the plurality of first groove structures J1 designed on the first flexible substrate 1031a can realize the differentiated design of shape, size, and spacing. In addition, differentiated design can also not be performed, which is not limited in the embodiments of the present disclosure. That is, the shapes of the plurality of first groove structures J1 on the first flexible substrate 1031a may be different or the same. The sizes of the plurality of first groove structures J1 on the first flexible substrate 1031a may be different or the same. The distance between two adjacent first groove structures J1 in the plurality of first groove structures J1 on the first flexible substrate 1031a may be different or the same.

Optionally, referring to FIGS. 7 to 9, in the case that the side of the first flexible substrate 1031a close to the first stretchable substrate 101 is provided with a plurality of first groove structures J1, the shapes of the orthographic projections of the plurality of first groove structures J1 on the first stretchable substrate 101 are the same, which can facilitate the manufacturing of the plurality of first groove structures J1. Alternatively, referring to FIG. 11, in the case that the first flexible substrate 1031a close to the first stretchable substrate 101 is provided with a plurality of first groove structures J1, the shapes of the orthographic projections of the plurality of first groove structures J1 on the first stretchable substrate 101 are different.

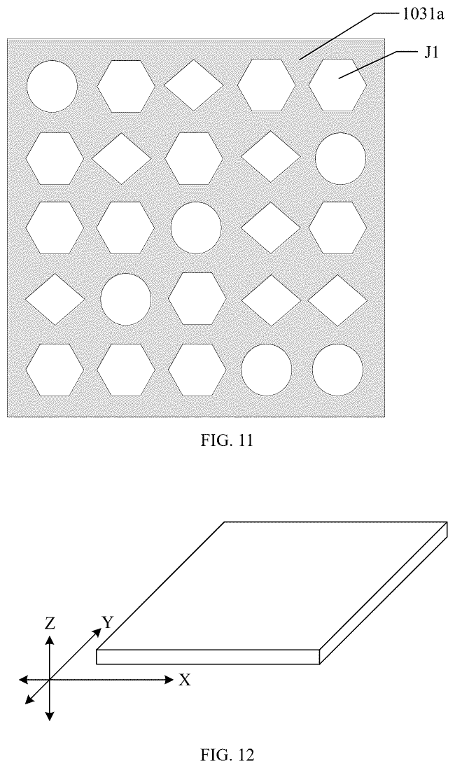

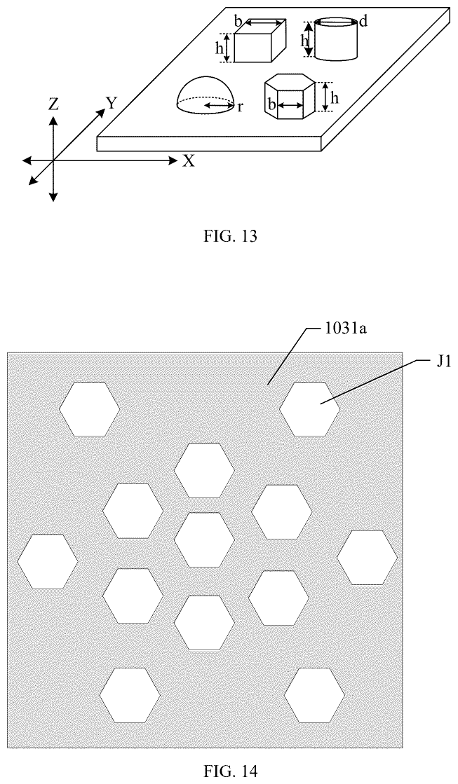

In the embodiments of the present disclosure, the shape of the first groove structure J1 affects the contact area between the first flexible substrate 1031a and the first adhesive layer 102. FIG. 12 is a schematic diagram of a first adhesive layer in the case that a first groove structure is not provided on a first flexible substrate according to some embodiments of the present disclosure. FIG. 13 is a schematic diagram of a first adhesive layer in the case that a first groove structure is provided on a first flexible substrate according to some embodiments of the present disclosure. Combined with FIG. 12 and FIG. 13, in the case that the shape of the first groove structure J1 is a cube, the contact area between the first flexible substrate 1031a and the first adhesive layer 102 increases by the side surface area of the cube: S1=4×h×b. Here, h is the depth of the first groove structure J1, and b is the length and width of the first groove structure J1. If the plurality of first groove structures J1 provided on the first flexible substrate 1031a are an array of m×n, then the contact area between the first flexible substrate 1031a and the first adhesive layer 102 increases by S1 total=m×n×4×h×b.

Combined with FIG. 12 and FIG. 13, in the case that the shape of the first groove structure J1 is a cylinder, the contact area between the first flexible substrate 1031a and the first adhesive layer 102 increases by the side surface area of the cylinder: S2=π×d×h. Here, h is the depth of the first groove structure J1, and d is the diameter of the first groove structure J1. If the plurality of first groove structures J1 disposed on the first flexible substrate 1031a is an array of m×n, then the contact area between the first flexible substrate 1031a and the first adhesive layer 102 increases by S2 total=m×n×π×d×h.

Combined with FIG. 12 and FIG. 13, in the case that the shape of the orthographic projection of the first groove structure J1 on the first stretchable substrate 101 is a regular hexahedron, the contact area between the first flexible substrate 1031a and the first adhesive layer 102 increases by the side surface area of the regular hexahedron: S3=6×h×b. Here, h is the depth of the first groove structure J1, and b is the side length of the first groove structure J1. If the plurality of first groove structures J1 provided on the first flexible substrate 1031a is an array of m×n, then the contact area between the first flexible substrate 1031a and the first adhesive layer 102 increases by S3 total=m×n×6×h×b.

Combined with FIG. 12 and FIG. 13, in the case that the shape of the orthographic projection of the first groove structure J1 on the first stretchable substrate 101 is a hemisphere, the contact area between the first flexible substrate 1031a and the first adhesive layer 102 increases by: S4=2πr2−πr2=πr2. Here, r is the radius of the hemisphere. If the plurality of first groove structures J1 provided on the first flexible substrate 1031a is an array of m×n, the contact area between the first flexible substrate 1031a and the first adhesive layer 102 increases by S4 total=m×n×πr2.

In the embodiments of the present disclosure, assuming that the adhesion force of the first adhesive layer 102 is λ (unit: kgf/cm²), the product of the increased contact area and the adhesion force is the increased fixing force of the display unit 1031. In other words, the larger the increased contact area is, the greater the increased fixing force of the display unit 1031 is; the smaller the increased contact area is, the smaller the increased fixing force of the display unit 1031 is.

Optionally, no matter what shape the first groove structure J1 is, in the case that the size of the first groove structure J1 is fixed, the increased contact area is positively correlated with the number of the first groove structures J1. That is, the greater the number of the first groove structures J1 is, the larger the increased contact area is; the smaller the number of the first groove structures J1 is, the smaller the increased contact area is.

In the embodiments of the present disclosure, to increase the contact area between the first flexible substrate 1031a and the first adhesive layer 102 as much as possible, the arrangement of the first groove structures J1 can be made the densest arrangement under the premise of process permission. In this way, the number of the first groove structures J1 can be large, and the contact area between the first flexible substrate 1031a and the first adhesive layer 102 can be large, and the fixing force of the display unit 1031 can be increased.

Optionally, in the case that the first groove structures J1 are arranged in the densest arrangement, the diameter of the minimum circumscribed circle of the first groove structures J1 may be 1.5 μm, and the distance between adjacent first groove structures J1 is also 1.5 μm.

In the embodiments of the present disclosure, in the case that a side of the first flexible substrate 1031a close to the first stretchable substrate 101 is provided with a plurality of first groove structures J1, regardless of whether the shapes of the orthographic projections of the plurality of first groove structures J1 on the first stretchable substrate 101 are the same, it is necessary to make the center points of the orthographic projections of the plurality of first groove structures J1 on the first stretchable substrate 101 form a centrally symmetric figure, and the symcenter of the centrally symmetric figure is the center of the island-shaped display region 101a.

Referring to FIG. 11, the shapes of the orthographic projections of the plurality of first groove structures J1 on the first stretchable substrate 101 are different (including circles, regular hexagons, and rhombuses), and the plurality of first groove structures J1 are arranged in an array in the first direction X and the second direction Y. In addition, the symcenter of the centrally symmetric figure formed by the center points of the orthographic projections of the plurality of first groove structures J1 on the first stretchable substrate 101 is the center of the island-shaped display region 101a. Alternatively, referring to FIG. 14, the shapes of the orthographic projections of the plurality of first groove structures J1 on the first stretchable substrate 101 are the same (regular hexagons). Although they are not arranged in an array, the center points of the orthographic projections of the plurality of first groove structures J1 on the first stretchable substrate 101 can also form a centrally symmetric figure, and the symcenter of the centrally symmetric figure is the center of the island-shaped display region 101a.

The reason why it is necessary to make the orthographic projections of the plurality of first groove structures J1 on the first stretchable substrate 101 centrally symmetrical with respect to the center of the island-shaped display region 101a is that: if the orthographic projections of the plurality of first groove structures J1 on the first stretchable substrate 101 are not centrally symmetrical with respect to the center of the island-shaped display region 101a, then the fixing force of the display unit 1031 in different regions will be different, and then in the case that the display panel is subjected to a tensile force, the region with the lower fixing force of the display unit 1031 will cause the display unit 1031 to separate from the first stretchable substrate 101.

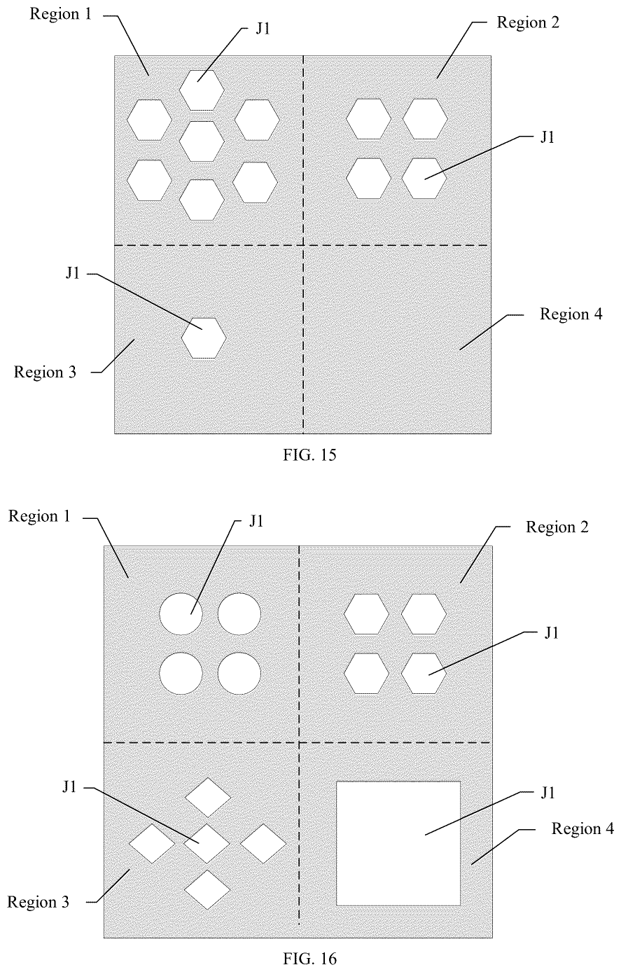

For example, referring to FIG. 15, the first flexible substrate 1031a is divided into four regions (region 1, region 2, region 3, and region 4), the first flexible substrate 1031a has seven first groove structures J1 in region 1, the first flexible substrate 1031a has four first groove structures J1 in region 2, the first flexible substrate 1031a has one first groove structure J1 in region 3, and the first flexible substrate 1031a has no first groove structure J1 in region 4. Taking the shape of the first groove structure J1 as a regular hexahedron as an example, the increased contact area in region 1 is S (region 1)=7×6×h×b. The increased contact area in region 2 is S (region 2)=4×6×h×b. The increased contact area in region 3 is S (region 3)=1×6×h×b. The increased contact area in region 4 is S (region 4)=0×6×h×b.

According to the comparison of the increased contact areas in the above four regions, the increased contact area in region 1 is greater than the increased contact area in region 2, the increased contact area in region 2 is greater than the increased contact area in region 3, and the increased contact area in region 3 is greater than the increased contact area in region 4. That is, S (region 1)>S (region 2)>S (region 3)>S (region 4). As a result, the fixing force of the display unit 1031 in region 1 is greater than the fixing force in region 2, the fixing force of the display unit 1031 in region 2 is greater than the fixing force in region 3, and the fixing force of the display unit 1031 in region 3 is greater than the fixing force in region 4. In the case that the display panel is subjected to a tensile force, the region where the fixing force of the display unit 1031 is lower (such as region 4) will cause the display unit 1031 to separate from the first stretchable substrate 101.

For example, referring to FIG. 16, the first flexible substrate 1031a is divided into four regions (region 1, region 2, region 3, and region 4), the first flexible substrate 1031a has four first groove structures J1 in region 1, the first flexible substrate 1031a has four first groove structures J1 in region 2, the first flexible substrate 1031a has five first groove structures J1 in region 3, and the first flexible substrate 1031a has one first groove structure J1 in region 4. In this design, the increased contact area in different regions can be determined according to the increased contact area and number of the first groove structures J1 of different shapes, and then the magnitude relationship of the fixing force of the display unit 1031 in different regions can be determined.

Generally, since the contact areas increased by the first groove structures J1 of different shapes are different, the contact areas increased in different regions can be made as similar as possible by adjusting the size, thereby ensuring that the fixing force of the display unit 1031 in different regions is as consistent as possible.

Therefore, in the embodiments of the present disclosure, in the case that the first flexible substrate 1031a includes a plurality of first groove structures J1 uniformly arranged in an array, when the shapes and sizes of the plurality of first groove structures J1 are the same, the fixing forces of the display units 1031 in different regions are substantially the same, thereby ensuring the fixing effects of different display units 1031 in different regions.

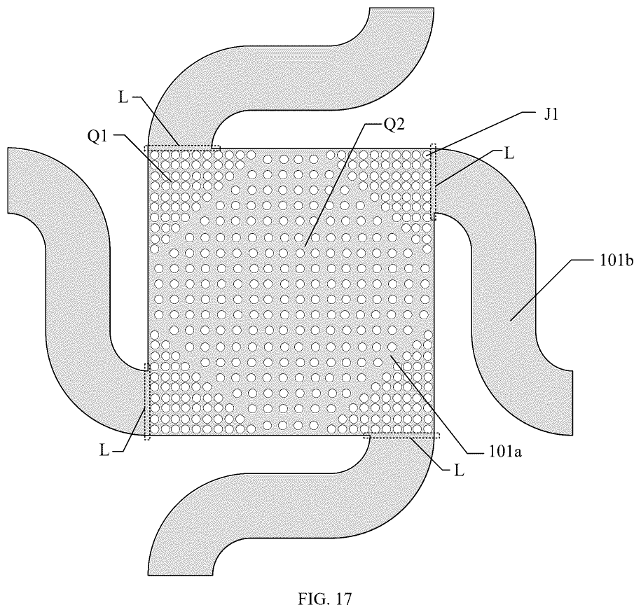

In the embodiments of the present disclosure, the distance between the edge of the island-shaped display region 101a and the stretchable region 101b is closer than the center of the island-shaped display region 101a, and it is more easily affected by the deformation of the stretchable region 101b. Therefore, referring to FIG. 17, the side of the first flexible substrate 1031a close to the first stretchable substrate 101 includes a first region Q1 and a second region Q2. The first region Q1 is closer to the connection L between the island-shaped display region 101a and the stretchable region 101b than the second region Q1. In the case that the side of the first flexible substrate 1031a close to the first stretchable substrate 101 is provided with a plurality of first groove structures J1, an arrangement density of the first groove structures J1 in the first region Q1 is greater than an arrangement density of the first groove structures J1 in the second region Q2. That is, the arrangement density of the first groove structures J1 of the first flexible substrate 1031a located at the edge of the island-shaped display region 101a close to the stretchable region 101b can be higher than the arrangement density of the first groove structures J1 of the first flexible substrate 1031a located at the center of the island-shaped display region 101a. Thus, the adhesion between the edge of the first flexible substrate 1031a located in the island-shaped display region 101a close to the stretchable region 101b and the first adhesive layer 102 can be increased, thereby reducing the influence of the deformation of the stretchable region 101b on the display unit 1031.

Optionally, referring to FIG. 17, the connection L between the island-shaped display region 101a and the stretchable region 101b is disposed at the four corners of the island-shaped display region 101a, and thus the first region Q1 can be the four corner regions of the first flexible substrate 1031a. In these four corner regions, the arrangement density of the first groove structures J1 is relatively high.

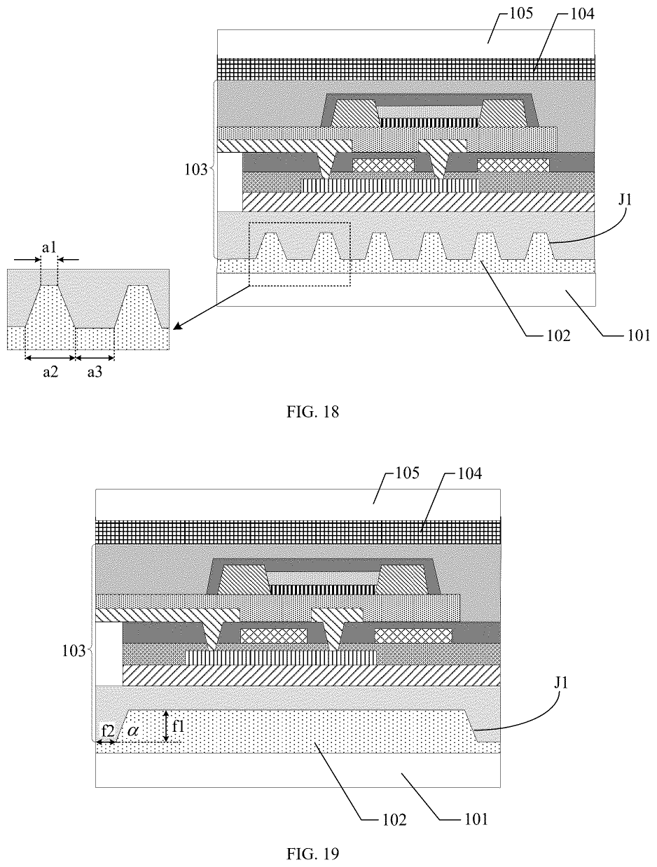

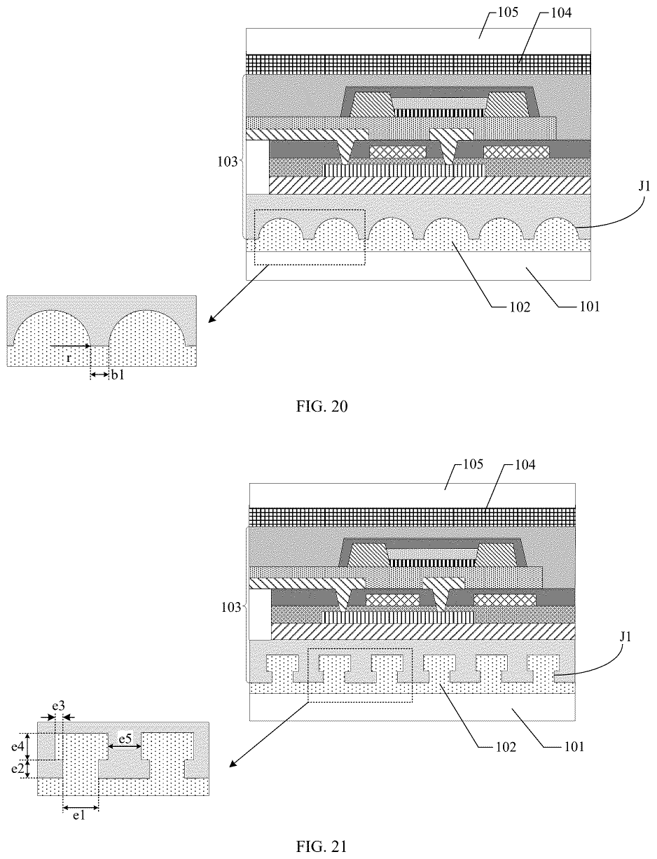

In the embodiments of the present disclosure, referring to FIGS. 18 and 19, a shape of an orthographic projection of the first groove structure J1 on a reference plane (which can be referred to as the shape of the cross section of the first groove structure J1) is a trapezoid. Referring to FIG. 20, the shape of the orthographic projection of the first groove structure J1 on the reference plane is a semicircle. Referring to FIG. 21, the shape of the orthographic projection of the first groove structure J1 on the reference plane is a T-shape. Alternatively, the shape of the orthographic projection of the first groove structure J1 on the reference plane is other shapes, such as a semi-ellipse, etc. The embodiments of the present disclosure do not limit the shape of the cross section of the first groove structure J1.

The reference plane is perpendicular to the supporting surface of the first stretchable substrate 101, and the reference plane is parallel to the first direction X or the second direction Y. That is, the orthographic projection of the first groove structure J1 on the reference plane may be the cross section of the first groove structure J1.

For example, in FIG. 18, in the case that the shape of the orthographic projection of the first groove structure J1 on the reference plane is a trapezoid, the width of the lower base a2 of the trapezoid ranges from 1.5 micrometers (μm) to 20 μm, and the width of the upper base a1 of the trapezoid is 50% to 90% of the width of the lower base. The spacing a3 between adjacent first groove structures J1 ranges from 1.5 μm to 20 μm.

In FIG. 20, in the case that the orthographic projection of the first groove structure J1 on the reference plane is a semicircle, the curvature radius r of the semicircle ranges from 5 μm to 35 μm, and the interval b1 between adjacent first groove structures J1 ranges from 1.5 μm to 20 μm.

In FIG. 21, in the case that the orthographic projection of the first groove structure J1 on the reference plane is a T-shape, the width e1 of the lower half of the T-shape ranges from 1.5 μm to 10 μm, and the height e2 ranges from 0.5 μm to 5 μm. The single-side width e3 of the upper half of the T-shape exceeds that of the lower half by 0.1 μm to 0.5 μm, and the height e4 of the upper half of the T-shape ranges from 0.05 μm to 1 μm. The spacing e5 between adjacent first groove structures J1 ranges from 1.5 μm to 20 μm.

In FIG. 19, in he case that the shape of the orthographic projection of the first groove structure J1 on the reference plane is a trapezoid, the height f1 of the trapezoid ranges from 0.5 μm to 6 μm, and the slope angle α of the side ranges from 30 degrees to 90 degrees. The distance f2 between the first groove structure J1 and the boundary of the first flexible substrate 1031a ranges from 5 μm to 20 μm.

In the embodiments of the present disclosure, the height (also referred to as the depth) of the first groove structure J1 may be 10% to 60% of the thickness of the first flexible substrate 1031a. The height of the first groove structure J1 may be determined according to the existing process capabilities. Optionally, the material of the first flexible substrate 1031a may be polyimide (PI), and the thickness of the first flexible substrate 1031a may range from 5 μm to 10 μm. In the case that the thickness of the first flexible substrate 1031a is 10 μm, and the maximum height of the first groove structure J1 may be 6 μm (for example, in the subsequent manufacturing process, the protrusion T2 may be formed by the superposition of an inorganic layer and a multi-layer resin, the thickness of the inorganic layer may be 2 μm, and the total thickness of the multi-layer resin may be 4 μm). It is estimated that the maximum ratio of the height of the first groove structure J1 to the thickness of the first flexible substrate 1031a is 60%. In the case that the thickness of the first flexible substrate 1031a is 5 μm, and the height of the first groove structure J1 can be as low as 0.5 μm (for example, in the subsequent manufacturing process, the protrusion T2 may be made of an inorganic material such as silicon oxide, and the thickness may be 0.5 μm). It is estimated that the minimum ratio of the height of the first groove structure J1 to the thickness of the first flexible substrate 1031a is 10%.

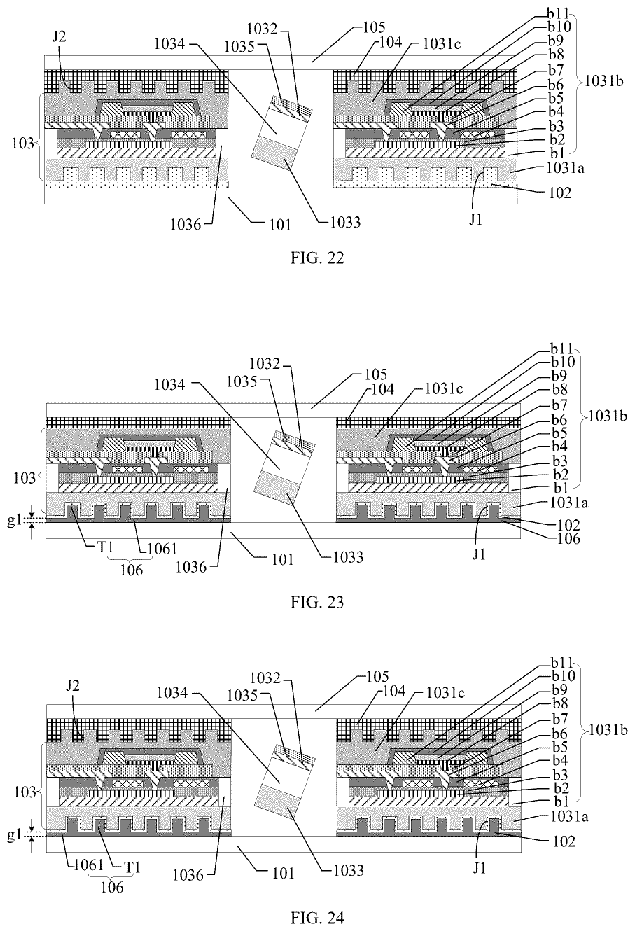

FIG. 22 is a cross-sectional schematic diagram of another display panel according to some embodiments of the present disclosure. Referring to FIG. 22, a side of the encapsulation film layer 1031c away from the first stretchable substrate 101 is provided with one or more second groove structures J2. A portion of the second adhesive layer 104 is disposed in the second groove structures J2, a portion of the surface of the second adhesive layer 104 close to the first flexible substrate 1031a is adhered to an inner wall of the second groove structure J2, and a surface of the second adhesive layer 104 close to the second stretchable substrate 105 is adhered to the second stretchable substrate 105.

By arranging the second groove structure J2 on the encapsulation film layer 1031c, the contact area between the encapsulation film layer 1031c and the second adhesive layer 104 can be increased, thereby increasing the stability of the display unit 1031 fixed between the first stretchable substrate 101 and the second stretchable substrate 105, and significantly reducing the deformation force on the display unit 1031 during the stretching process.

Optionally, the shape of the second groove structure J2 can be set with reference to the shape of the first groove structure J1. In addition, the shape of the second groove structure J2 may be the same as or different from the shape of the first groove structure J1, which is not limited in the embodiments of the present disclosure.

Optionally, the shape of an orthographic projection of the second groove structure J2 on the first stretchable substrate 101 is one of a circle, a square, a regular hexagon, and a rhombus. In addition, in the case that the side of the encapsulation film layer 1031c away from the first stretchable substrate 101 is provided with a plurality of first groove structures J1, the shapes of the orthographic projections of the plurality of first groove structures J1 on the first stretchable substrate 101 are the same, or the shapes of the orthographic projections of the plurality of first groove structures J1 on the first stretchable substrate 101 are different.

In addition, no matter what shape the second groove structure J2 is, in the case that the size of the second groove structure J2 is fixed, the increased contact area between the encapsulation film layer 1031c and the second adhesive layer 104 is positively correlated with the number of the second groove structures J2. That is, the greater the number of the second groove structures J2 is, the larger the increased contact area between the encapsulation film layer 1031c and the second adhesive layer 104 is; the smaller the number of the second groove structures J2 is, the smaller the increased contact area between the encapsulation film layer 1031c and the second adhesive layer 104 is.

In the embodiments of the present disclosure, to increase the contact area between the encapsulation film layer 1031c and the second adhesive layer 104 as much as possible, the second groove structures J2 can be arranged in the densest arrangement under the premise of process permission. In this way, the number of second groove structures J2 can be large, and the contact area between the encapsulation film layer 1031c and the second adhesive layer 104 can be large, and the fixing force of the display unit 1031 can be increased.

In the case that the side of the encapsulation film layer 1031c away from the first stretchable substrate 101 is provided with a plurality of second groove structures J2, regardless of whether the shapes of the orthographic projections of the plurality of second groove structures J2 on the first stretchable substrate 101 are the same, it is necessary to make the orthographic projections of the plurality of second groove structures J2 on the first stretchable substrate 101 centrally symmetrical with respect to the center of the island-shaped display region 101a.

In the embodiments of the present disclosure, the distance between the edge of the island-shaped display region 101a and the stretchable region 101b is closer than the center of the island-shaped display region 101a, and it is more susceptible to the deformation of the stretchable region 101b. Therefore, the arrangement density of the second groove structures J2 of the encapsulation film layer 1031c located at the edge of the island-shaped display region 101a close to the stretchable region 101b can be higher than the arrangement density of the first groove structures J1 of the encapsulation film layer 1031c located at the center of the island-shaped display region 101a. In this way, the adhesion between the edge of the encapsulation film layer 1031c located at the island-shaped display region 101a and the second adhesive layer 104 can be increased, and the influence of the deformation of the stretchable region 101b on the display unit 1031 can be reduced. The arrangement of the second groove structures J2 can be similar to the arrangement of the first groove structures J1 in FIG. 17.

In the embodiments of the present disclosure, the shape of the orthographic projection of the first groove structure J1 on the reference plane is a trapezoid, a semicircle, a T-shape, a semi-ellipse, etc. The embodiments of the present disclosure do not limit the shape of the cross section of the second groove structure J2.

Optionally, the size of the second groove structure J2 can be set with reference to the size of the first groove structure J1. In addition, the size of the second groove structure J2 may be the same as or different from the size of the first groove structure J1, which is not limited in the embodiments of the present disclosure.

In the embodiments of the present disclosure, the encapsulation film layer 1031c may include a first encapsulation layer, a second encapsulation layer, and a third encapsulation layer that are stacked in sequence in a direction away from the first stretchable substrate 101. The materials of the first encapsulation layer and the third encapsulation layer are inorganic materials, and the material of the second encapsulation layer may be an organic material. That is, the encapsulation film layer 1031c may be a three-layer structure of inorganic+organic+inorganic.

For example, the first encapsulation layer and the third encapsulation layer may be made of one or more inorganic oxides such as silicon nitride (SiNx), silicon oxide (SiOx), and silicon oxynitride (SiOxNy). The second encapsulation layer may be made of a resin material. The resin may be a thermoplastic resin or a thermosetting resin, the thermoplastic resin may include an acrylic (PMMA) resin, and the thermosetting resin may include an epoxy resin.

Optionally, the second encapsulation layer may be made by ink jet printing (IJP), and the second encapsulation layer may be called an IJP layer. The first encapsulation layer and the third encapsulation layer may be made by chemical vapor deposition (CVD). The first encapsulation layer may be called a CVD1 layer, and the second encapsulation layer may be called a CVD2 layer.

To ensure the encapsulation effect of the encapsulation film layer 1031c, the thickness of the third encapsulation layer needs to be greater than or equal to 600 nm. In the embodiments of the present disclosure, since the second groove structure J2 is provided on the encapsulation film layer 1031c away from the first stretchable substrate 101, and the second groove structure J2 is obtained by local etching, when manufacturing the third encapsulation layer, a thicker third encapsulation film may be manufactured first, and then the thicker third encapsulation film may be etched to obtain one or more second groove structures J2.

Exemplarily, the thickness of the thicker third encapsulation film may be greater than or equal to 1100 nm, that is, the third encapsulation film is thickened by 500 nm. The thickened 500 nm may be used for local etching to form the second groove structure J2, and 600 nm is retained below to ensure the encapsulation effect of the encapsulation film layer 1031c. In this case, one or more second groove structures J2 are disposed on a surface of the third encapsulation layer away from the first stretchable substrate 101, and the distance between the surface of the second groove structure J2 close to the first stretchable substrate 101 and the surface of the third encapsulation layer close to the first stretchable substrate 101 is greater than or equal to 600 nm.

Optionally, since the rigidity of the first stretchable substrate 101 is relatively low, the first adhesive layer 102 may be made of a material having a certain rigidity, so as to improve the resistance to deformation of the display unit 1031 in the island-shaped display region 101a. For example, the Young's modulus of PDMS ranges from 1 megapascal (MP) to 10MP, that is, the rigidity of the first stretchable substrate 101 is relatively low, so the Young's modulus of the material selected for the first adhesive layer 102 may be greater than or equal to 5 gigapascals (GPa).

If the Young's modulus of the material selected for the first adhesive layer 102 is relatively small (for example, ranges from 500 kilopascals (kPa) to 3.5 MPa), that is, the rigidity of the first adhesive layer 102 is relatively low, the display panel 100 may also include a fixed film layer 106. Referring to FIGS. 23 and 24, the fixed film layer 106 is disposed in the island-shaped display region 101a and between the first adhesive layer 102 and the first stretchable substrate 101, and the first adhesive layer 102 is used to connect the fixed film layer 106 and the first flexible substrate 1031a.

Optionally, the material of the fixed film layer 106 may be at least one of inorganic materials such as SiNx, SiON, and SiO. Since the Young's modulus of the fixed film layer 106 ranges from 1 GPa to 100 GPa, the Young's modulus is relatively large, and thus the fixed film layer 106 can provide the display unit 1031 in the island-shaped display region 101a with anti-deformation capability.

Referring to FIGS. 23 and 24, in the case that the side of the first flexible substrate 1031a close to the first stretchable substrate 101 is provided with one or more first groove structures J1, the fixed film layer 106 includes a fixed layer 1061, and one or more protruding structures T1 disposed on a side of the fixed layer 1061 away from the first stretchable substrate 101. An orthographic projection of each protruding structure T1 on the first stretchable substrate 101 is within the orthographic projection of a corresponding first groove structure J1 on the first stretchable substrate 101.

The orthographic projection of the protruding structure T1 on the first stretchable substrate 101 is within the orthographic projection of the corresponding first groove structure J1 on the first stretchable substrate 101, which may mean that: the area of the orthographic projection of the protruding structure T1 on the first stretchable substrate 101 is smaller than the area of the corresponding first groove structure J1 on the first stretchable substrate 101, and at least a portion of the protruding structure T1 can be inserted into the first groove structure J1. That is, the width of the protruding structure T1 in the fixed film layer 106 is smaller than the width of the first groove structure J1, such that the first groove structure J1 can form a better fit with the protruding structure T1, thereby effectively increasing the contact area between the first adhesive layer 102 and the fixed film layer 106 and the first flexible substrate 1031a, and further improving the adhering force between the first adhesive layer 102 and the fixed film layer 106 and the first flexible substrate 1031a.

Optionally, the height of the protruding structure T1 is smaller than the height of the first groove structure J1, and the thickness g1 of the fixed layer 1061 is greater than or equal to 1 μm. In this way, it can be ensured that the fixed film layer 106 has good strength.

In the embodiments of the present disclosure, the display unit 1031 includes a pixel circuit and a light-emitting unit. The pixel circuit includes a plurality of thin film transistors and at least one storage capacitor. Optionally, the pixel circuit may include seven thin film transistors and one storage capacitor, i.e., the pixel circuit is a 7TIC pixel circuit. Alternatively, the pixel circuit may include other numbers of thin film transistors (TFT) and other numbers of storage capacitors. The embodiments of the present disclosure do not limit the number of thin film transistors included in the pixel circuit and the number of storage capacitors included.

Each thin film transistor includes a gate electrode, a source electrode, and a drain electrode. The pixel circuit includes a plurality of thin film transistors that are connected to achieve the function of driving the light-emitting unit to emit light.

Referring to FIG. 5 and FIGS. 22 to 24, the display layer 1031b includes a buffer layer (buffer) b1, an active layer (ACT) b2, a gate insulator (GI) b3, a gate layer (gate) b4, an inter-level dielectric (ILD) layer b5, a source-drain electrode layer b6, a planarization layer (PLN) b7, an anode layer b8, a pixel definition layer (PDL) b9, a light-emitting layer b10, and a cathode layer b11. The buffer layer b1, the active layer b2, the gate insulator b3, the gate layer b4, the inter-level dielectric layer b5, the source-drain layer electrode b6 (the source-drain electrode layer may also be referred to as an SD layer), and the planarization layer b7 are used to form a pixel circuit of the display unit 1031. The anode layer b8, the pixel defining layer b9, the light-emitting layer b10 (the light-emitting layer may also be referred to as an EL functional layer), and the cathode layer b11 are used to form a light-emitting unit of the display unit 1031.

The active layer b2 includes an active pattern, and the active pattern includes a source region, a drain region, and a channel region. The source-drain layer includes a source electrode and a drain electrode, and the source electrode is connected to the source region through a first via hole in the interlayer dielectric layer and the gate insulating layer, and the drain electrode is connected to the drain region through a second via hole in the interlayer dielectric layer and the gate insulating layer.

The gate layer b4 includes a gate pattern, and the channel region is an overlapping region of an orthographic projection of the gate pattern on the first stretchable substrate 101 and an orthographic projection of the active pattern on the first stretchable substrate 101.

Optionally, the material of the source-drain electrode layer b6 may be a metal or a metal alloy. For example, the material of the source-drain electrode layer b6 may be one of titanium, aluminum, molybdenum, copper, silver, and gold, or the material of the source-drain electrode layer b6 may be a titanium aluminum alloy and an aluminum-neodymium alloy. In addition, the material of the source-drain electrode layer b6 may also be a conductive material with good tensile properties, such as nano silver wires, carbon nanotubes, graphene, and liquid metal. Alternatively, the material of the source-drain electrode layer b6 may also be an organic mixture, such as carbon nanotubes, silver nanosheets, stretchable resins, and rubber. The source-drain electrode layer b6 may be graphically designed using processes such as inkjet printing, 3D printing, printing, and nanoimprinting.

Optionally, the light-emitting layer b9 may be manufactured by an evaporation process. The anode layer b8 and the cathode layer b10 are both in contact and electrically connected with the light-emitting layer b9, and the anode layer b8 and the cathode layer b10 jointly realize electrical control of the light-emitting layer b9, such that the light-emitting layer b9 can emit light. The material of the cathode layer b10 may be a metal or a metal alloy, such as at least one of magnesium (Mg) and silver (Ag), or the material of the cathode layer b10 may be a transparent conductive oxide such as indium zinc oxide (IZO).

The film layers in the display layer 1031b (such as the light-emitting layer and the cathode layer) are easily corroded by water vapor and oxygen. Since the encapsulation film layer 1031c is arranged above the display layer 1031c, the encapsulation film layer 1031c can protect the film layers in the display layer 1031b and avoid water and oxygen corrosion.

In the embodiments of the present disclosure, the display substrate 103 includes a plurality of signal lines 1032 located in the source-drain electrode layer. That is, the plurality of signal lines 1032 and the source electrode and drain electrode of the thin film transistor may be manufactured from the same material and through the same patterning process. The second flexible film layer 1035 included in the display substrate 103 and the planarization layer are in the same layer. That is, the second flexible film layer 1035 and the planarization layer b7 may be manufactured from the same material and through the same patterning process.

To enable the stretchable region 101b to be stretched, the inorganic material film layer in the stretchable region 101b needs to be removed. This will result in a large step difference between the surface used to form the source-drain electrode layer in the island-shaped display region 101a and the surface used to form the source-drain electrode layer b6 in the stretchable region 101b when the source-drain electrode layer b6 is formed, which may affect the wiring of the signal line 1032 in the stretchable region 101b. Therefore, to reduce the surface step difference between the two regions, one layer of organic material layer (i.e., the first flexible film layer 1034) can be arranged in the stretchable region 101b alone to fill the void after the inorganic material film layer is removed, such that the surface used to form the source-drain electrode layer in the island-shaped display region 101a and the surface used to form the source-drain electrode layer b6 in the stretchable region 101b are roughly located in the same plane, reducing the wiring difficulty of the signal lines 1032. Optionally, the material of the first flexible film layer 1034 may be resin.

Optionally, the distance in the third direction Z between the surface of the first flexible film layer 1034 away from the second flexible substrate 1033 and the surface of the interlayer dielectric layer b5 away from the first flexible substrate 1031a is less than a distance threshold. That is, the surface of the island-shaped display region 101a for forming the source-drain electrode layer b6 and the surface of the stretchable region 101b for forming the source-drain electrode layer b6 are substantially located in the same plane.

Optionally, referring to FIG. 5, the display substrate 103 may include a flexible layer 1036 disposed in the island-shaped display region 101a, and the flexible layer 1036 may be manufactured together with the first flexible film layer 1034. The material of the flexible layer 1036 may be resin.

In summary, in a display panel provided by the embodiments of the present disclosure, for island-shaped display regions included in a first stretchable substrate, the first stretchable substrate and a display substrate are adhered by a first adhesive layer, and a second stretchable substrate and the display substrate is adhered by a second adhesive layer, the display substrate can be fixed between the first stretchable substrate and the second stretchable substrate. For the stretchable region included in the first stretchable substrate in the display panel, no adhesive layer is provided to fix the display substrate. Thus, after the display panel is subjected to a stretching force, the portion of the display panel located in the stretchable region can be stretched not only in various directions on the surface where the first stretchable substrate is located, but also in a direction perpendicular to the first stretchable substrate. That is, the deformation flexibility of the display panel is high, which increases the stretching amount of the display panel.

In the embodiments of the present disclosure, through the special design of the display panel, when the display panel (stretchable panel) is deformed by external force, the display unit (pixel circuit and light-emitting unit) in the island-shaped display region has almost no deformation, while the stretchable region can withstand a larger deformation, thereby ensuring that the display panel can work normally under stretching conditions.

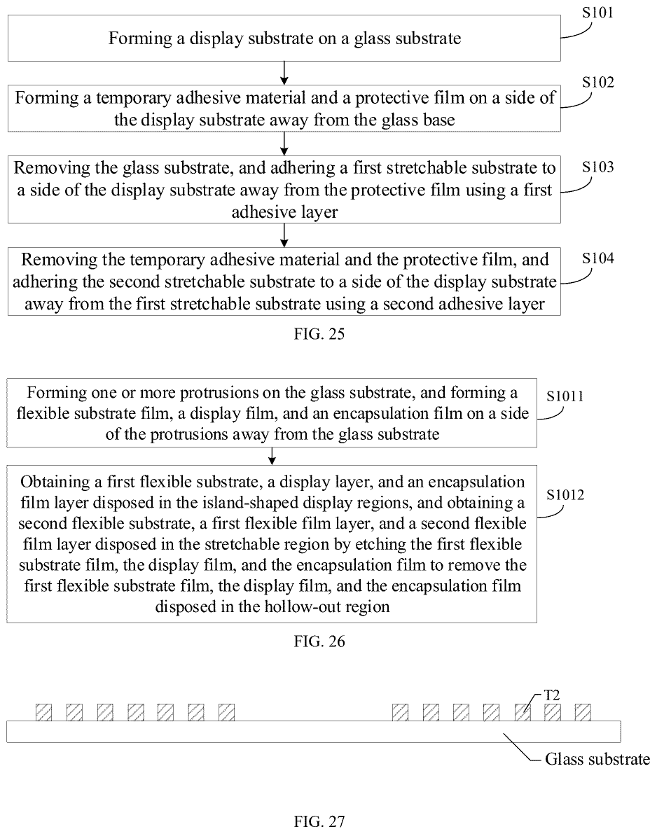

FIG. 25 is a flowchart of a method for manufacturing a display panel according to some embodiments of the present disclosure. Referring to FIG. 25, the method includes:

In step S101, a display substrate is formed on a glass substrate.

In the embodiments of the present disclosure, when forming the display panel, a substrate with a certain rigidity can be obtained first, and a display substrate 103 is formed on the substrate. The rigid substrate can be a glass substrate. The display substrate 103 includes a plurality of display units 1031.

Referring to FIG. 26, in the case that one or more first groove structures J1 are provided on the first flexible substrate 1031a of the display substrate 103, the process of forming the display substrate 103 includes:

In step S1011, one or more protrusions are formed on the glass substrate, and a flexible substrate film, a display film, and an encapsulation film are formed on a side of the protrusions away from the glass substrate.

Referring to FIG. 27, the material of the protrusions T2 may include silicon oxide and transparent resin. The protrusions T2 may be formed by exposure, development, etching, and other processes, or may be formed by inkjet printing or nano-imprinting.

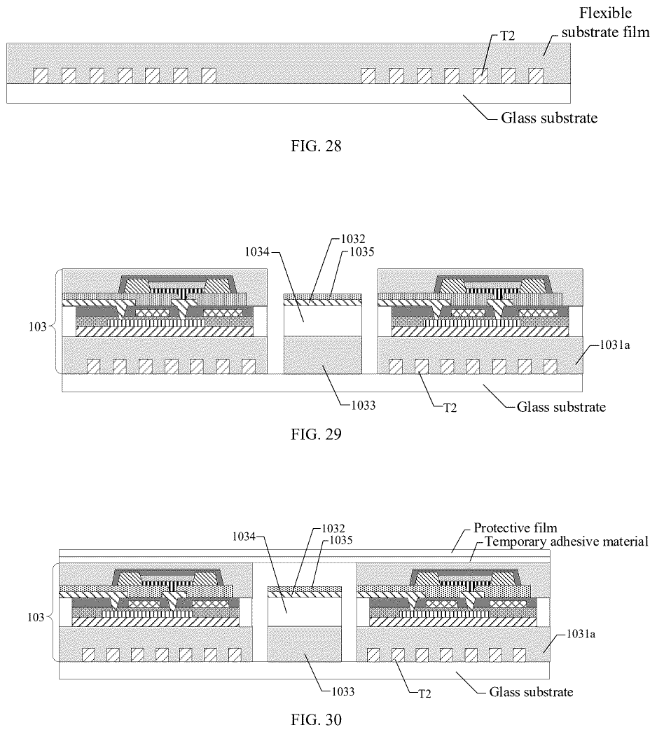

Referring to FIG. 28, after the protrusions T2 are formed, the material of the liquid flexible substrate can be coated on the glass substrate. Since the protrusions T2 have been formed before the liquid flexible substrate material is coated, when the liquid flexible substrate material is coated, the region of the protrusions T2 will not be coated with the material of the flexible substrate, such that an uneven structure can be formed on the flexible substrate. After the coating process, the material of the flexible substrate is subjected to a curing process, and then the uneven flexible substrate is fixed to obtain a flexible substrate film. The uneven structure can be used to represent the first groove structures J1.

Next, the display film and the encapsulation film are manufactured on the flexible substrate film. The display film may include each film layer in the display unit 1031 (the portion of the film layer located in the hollow-out region 101c is not etched at this stage, which is the entire film layer). The encapsulation film may include a CVD1 film, an IJP film, and a CVD2 film.

In step S1012, the first flexible substrate, the display layer, and the encapsulation film layer located in the island-shaped display regions are obtained, and the second flexible substrate, the first flexible film layer, and the second flexible film layer located in the stretchable region are obtained by etching the first flexible substrate film, the display film, and the encapsulation film to remove the portion of the first flexible substrate film, the display film, and the encapsulation film located in the hollow-out region.

Referring to FIG. 29, an etching process can be used to remove the portion located in the hollow region 101 c, thereby facilitating obtaining a stretchable display panel.

In step S102, a temporary adhesive material and a protective film are formed on a side of the display substrate away from the glass base.

In the embodiments of the present disclosure, referring to FIG. 30, the temporary adhesive is disposed on the side of the display substrate away from the glass substrate, and the protective film is disposed on a side of the temporary adhesive away from the display substrate. The temporary adhesive is used to adhere the display substrate to the protective film. The temporary adhesive and the protective film are used to protect the side of the display substrate 103 away from the glass substrate to avoid affecting the display substrate 103 during the manufacturing process of the display panel.

In step S103, the glass substrate is removed, and a first adhesive layer is used to adhere the first stretchable substrate to a side of the display substrate away from the protective film.

In the embodiments of the present disclosure, since the tensile properties of the glass substrate are relatively poor, after the display substrate 103 is manufactured, the glass substrate can be removed by a laser stripping process, and the first stretchable substrate 101 with better tensile properties can be adhered to the side of the display substrate 103 away from the protective film using the first adhesive layer 102.

Optionally, the protrusions T2 are formed on the glass substrate and cannot be affected by laser stripping. If the protrusions T2 are formed on the glass substrate, the protrusions T2 can be separated from the glass substrate and the flexible substrate during the process of removing the glass substrate, such that one or more first groove structures J1 are formed on the lower surface of the first flexible substrate 1031a.

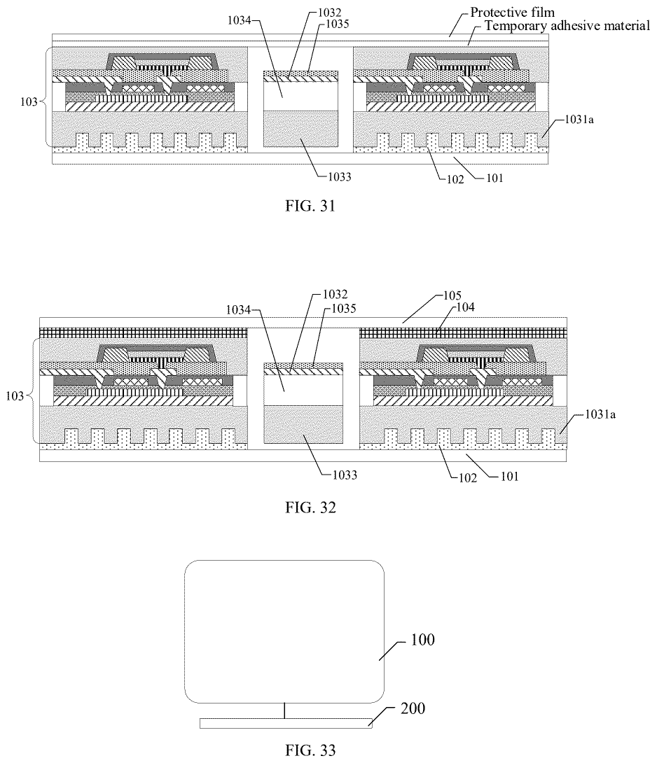

In addition, after the glass substrate and the protrusions T2 are removed, an adhesive material can be formed on the first flexible substrate 1031a by dispensing or inkjet printing, and then the first stretchable substrate 101 is attached to the bottom of the first flexible substrate 1031a, and finally, the adhesive material is cured. As shown in FIG. 31, the first adhesive layer 102 is obtained, and the first flexible substrate 1031a and the first stretchable substrate 101 are adhered.

In step S104, the temporary adhesive material and the protective film are removed, and the second stretchable substrate is adhered to a side of the display substrate away from the first stretchable substrate using a second adhesive layer.

In the embodiments of the present disclosure, after the first stretchable substrate 101 is adhered, the temporary adhesive material and the protective film on the side of the display substrate 103 away from the first stretchable substrate 101 can be removed (peeled off). Then, the second stretchable substrate 105 with better tensile properties can be adhered to the side of the display substrate 103 away from the first stretchable substrate 101 using the second adhesive layer 104.

Specifically, a process such as dispensing or inkjet printing can be used to form an adhesive material on the side of the encapsulation film layer 1031c away from the first stretchable substrate 101, and then the second stretchable substrate 105 is adhered to the top of the encapsulation film layer 1031c, and finally, the adhesive material is cured. As shown in FIG. 32, the second adhesive layer 104 is obtained, and the encapsulation film layer 1031c and the second stretchable substrate 105 are adhered.

In the embodiments of the present disclosure, the first stretchable substrate 101 includes a plurality of island-shaped display regions 101a, a stretchable region 101b connecting adjacent island-shaped display regions 101a, and a hollow-out region 101c between the island-shaped display region 101a and the stretchable regions 101b. The display unit 1031 is disposed in the island-shaped display region 101a. The first adhesive layer 102 is disposed between the display substrate 103 and the first stretchable substrate 101, and the first adhesive layer 102 is used to adhere the display substrate 103 to the first stretchable substrate 101, such that the display substrate 103 is fixed on the first stretchable substrate 101.

An orthographic projection of the first adhesive layer 102 on the first stretchable substrate 101 is within an orthographic projection of the display unit 1031 on the first stretchable substrate 101. That is, the first adhesive layer 102 is only provided in the island-shaped display region 101a, and is used to adhere the portion of the display substrate 103 located in the island-shaped display region 101a and the island-shaped display region 101a of the first stretchable substrate 101. In addition, the first adhesive layer 102 does not need to be provided in the stretchable region 101b, and the portion of the display substrate 103 located in the stretchable region 101b does not need to be adhered to the stretchable region 101b of the first stretchable substrate 101, and the portion of the display substrate 103 located in the stretchable region 101b only needs to be provided on the first stretchable substrate 101.

The second adhesive layer 104 is disposed on the side of the display substrate 103 away from the first stretchable substrate 101, and the second stretchable substrate 105 is disposed on a side of the second adhesive layer 104 away from the display substrate 103. That is, the second adhesive layer 104 is disposed between the display substrate 103 and the second stretchable substrate 105, and is used to adhere the display substrate 103 to the second stretchable substrate 105, such that the display substrate 103 is fixed between the first stretchable substrate 101 and the second stretchable substrate 105.

An orthographic projection of the second adhesive layer 104 on the first stretchable substrate 101 is within the orthographic projection of the display unit 1031 on the first stretchable substrate 101. That is, the second adhesive layer 104 is only provided in the island-shaped display region 101a, and is used to adhere the portion of the display substrate 103 located in the island-shaped display region 101a and the portion of the second stretchable substrate 105 located in the island-shaped display region 101a. In addition, the second adhesive layer 104 does not need to be provided in the stretchable region 101b, and the portion of the display substrate 103 located in the stretchable region 101b does not need to be adhered to the portion of the second stretchable substrate 105 located in the stretchable region 101b.

In the embodiments of the present disclosure, in the island-shaped display region 101a, the display substrate 103 is fixed between two stretchable substrates by the first adhesive layer 102 and the second adhesive layer 104. And no adhesive layer is provided in the stretchable region 101b for fixing. Since the display panel is not fixed by adhesive in a vertical direction (a third direction Z) perpendicular to the supporting surface of the stretchable substrate, after the display panel 100 is subjected to a tensile force, the portion of the display panel located in the stretchable region 101b can generate strain in the vertical direction. In addition, the portion of the display panel located in the stretchable region 101b can also be stretched in various directions (such as the first direction X and the second direction Y perpendicular to each other) on the surface of the first stretchable substrate 101. That is, the deformation flexibility of the display panel 100 is high, which increases the stretching amount of the display panel 100. The plurality of island-shaped display regions 101a can be arranged in an array in the first direction X and the second direction Y.

In summary, the embodiments of the present disclosure provide a method for manufacturing a display panel. In the display panel manufactured by the method, for island-shaped display regions included in a first stretchable substrate, the first stretchable substrate and a display substrate are adhered by a first adhesive layer, and a second stretchable substrate and the display substrate are adhered by a second adhesive layer, the display substrate can be fixed between the first stretchable substrate and the second stretchable substrate. For the stretchable region included in the first stretchable substrate in the display panel, no adhesive layer is provided to fix the display substrate. Thus, after the display panel is subjected to a stretching force, the portion of the display panel located in the stretchable region can be stretched not only in various directions on the surface where the first stretchable substrate is located, but also in a direction perpendicular to the first stretchable substrate. That is, the deformation flexibility of the display panel is high, which increases the stretching amount of the display panel.

FIG. 33 is a schematic structural diagram of a display device according to some embodiments of the present disclosure. Referring to FIG. 33, the display device includes: a power supply component 200 and a display panel 100 provided in the above embodiments. The power supply component 200 is connected to the display panel 100 to supply power to the display panel 100.

Optionally, the display panel 100 may be an organic light-emitting diode (OLED) display panel, and the display device may be an OLED display device. Optionally, the display device may be any appropriate display device, including but not limited to any product or component with a display function, such as a mobile phone, a tablet computer, a television, a monitor, a notebook computer, a digital photo frame, a navigator, and an e-book.

Since the display device can have substantially the same technical effects as the display panel described in the previous embodiments, the technical effects of the display device will not be repeatedly described here for the purpose of brevity.

The terms used in the embodiments of the present disclosure are only used to explain the embodiments of the present disclosure and are not intended to limit the present disclosure. Unless otherwise defined, the technical terms or scientific terms used in the embodiments of the present disclosure should be the common meanings understood by those of ordinary skills in the field to which the present disclosure belongs.

The terms used in the embodiments of the present disclosure are only used to explain the embodiments of the present disclosure, and are not intended to limit the present disclosure. Unless otherwise defined, the technical terms or scientific terms used in the embodiments of the present disclosure should be the common meanings understood by those of ordinary skills in the field to which the present disclosure belongs. The words “first,” “second,” “third,” and similar words used in the specification and claims of the present disclosure do not indicate any order, quantity, or importance, but are only used to distinguish different components. Similarly, words such as “one” or “a” do not indicate a quantity limit, but indicate that there is at least one. Words such as “include” or “comprise” mean that the elements or objects appearing in front of “include” or “comprise” include the elements or objects listed after “include” or “comprise” and their equivalents, and do not exclude other elements or objects. Words such as “connect” or “connected” are not limited to physical or mechanical connections, but may include electrical connections, whether direct or indirect. “Up,” “down,” “left,” “right,” and the like are only used to indicate relative positional relationships. When the absolute position of the described object changes, the relative positional relationship may also change accordingly.

The above description is only optional embodiments of the present disclosure and is not intended to limit the present disclosure. Any modifications, equivalent substitutions, improvements, etc. made within the spirit and principles of the present disclosure shall be included in the protection scope of the present disclosure.

1. A display panel, comprising:
a first stretchable substrate, wherein the first stretchable substrate comprises a plurality of island-shaped display regions, a stretchable region connecting adjacent island-shaped display regions, and a hollow-out region between one of the island-shaped display regions and the stretchable region;
a display substrate, wherein the display substrate comprises a plurality of display units disposed in the island-shaped display regions;
a first adhesive layer disposed between the display substrate and the first stretchable substrate, wherein an orthographic projection of the first adhesive layer on the first stretchable substrate is within orthographic projections of the display units on the first stretchable substrate; and
a second adhesive layer disposed on a side of the display substrate away from the first stretchable substrate, and a second stretchable substrate disposed on a side of the second adhesive layer away from the display substrate, wherein an orthographic projection of the second adhesive layer on the first stretchable substrate is within the orthographic projections of the display units on the first stretchable substrate.

2. The display panel according to claim 1, wherein each of the display units comprises a first flexible substrate, a display layer, and an encapsulation film layer that are stacked in sequence in a direction away from the first stretchable substrate; wherein
for each of the island-shaped display regions, the display substrate comprises at least one display unit disposed in the island-shaped display region, and each of the display units comprises a plurality of sub-pixels.

3. The display panel according to claim 2, wherein the display substrate further comprises a plurality of signal lines, wherein a portion of each of the signal lines is disposed in the island-shaped display region, and another portion of each of the signal lines is disposed in the stretchable region; and
the portion of each of the signal lines located in the island-shaped display region is connected to the display layer of the display unit, and the signal line is configured to transmit a driving signal provided by a driver circuit.

4. The display panel according to claim 3, wherein the display substrate further comprises a second flexible substrate, a first flexible film layer, and a second flexible film layer that are disposed in the stretchable region and stacked in sequence in the direction away from the first stretchable substrate; wherein
the portion of each of the signal lines located in the stretchable region is disposed between the first flexible film layer and the second flexible film layer.

5. The display panel according to claim 2, wherein a side of the first flexible substrate close to the first stretchable substrate is provided with one or more first groove structures; wherein
a portion of the first adhesive layer is disposed in each of the first groove structures, a portion of a surface of the first adhesive layer close to the first flexible substrate is adhered to an inner wall of each of the first groove structures, and a surface of the first adhesive layer close to the first stretchable substrate is adhered to the first stretchable substrate.

6. The display panel according to claim 5, wherein the side of the first flexible substrate close to the first stretchable substrate comprises a first region and a second region, the first region being closer to a connection between the island-shaped display region and the stretchable region than the second region; wherein
in a case that the side of the first flexible substrate close to the first stretchable substrate is provided with a plurality of first groove structures, an arrangement density of the first groove structures in the first region is greater than an arrangement density of the first groove structures in the second region.

7. The display panel according to claim 5, wherein a shape of an orthographic projection of each of the first groove structures on the first stretchable substrate is a circle, an ellipse, a square, a regular hexagon, or a rhombus.

8. The display panel according to claim 5, wherein in a case that the side of the first flexible substrate close to the first stretchable substrate is provided with a plurality of first groove structures, shapes of orthographic projections of the plurality of first groove structures on the first stretchable substrate are the same.

9. The display panel according to claim 5, wherein in a case that the side of the first flexible substrate close to the first stretchable substrate is provided with a plurality of first groove structures, center points of orthographic projections of the plurality of first groove structures on the first stretchable substrate constitute a centrally symmetric figure, and a symcenter of the centrally symmetric figure is a center of the island-shaped display region.

10. (canceled)

11. The display panel according to claim 5, wherein the plurality of island-shaped display regions are arranged in an array in a first direction and a second direction; a shape of an orthographic projection of each of the first groove structures on a reference plane is one of a trapezoid, a semicircle, a semi-ellipse, and a T-shape; wherein
the reference plane is perpendicular to a supporting surface of the first stretchable substrate, and the reference plane is parallel to the first direction or the second direction.

12. The display panel according to claim 2, wherein a side of the encapsulation film layer away from the first stretchable substrate is provided with one or more second groove structures; wherein
a portion of the second adhesive layer is disposed in the second groove structures, a portion of a surface of the second adhesive layer close to the first flexible substrate is adhered to an inner wall of the second groove structure, and a surface of the second adhesive layer close to the second stretchable substrate is adhered to the second stretchable substrate.

13. The display panel according to claim 12, wherein the encapsulation film layer comprises a first encapsulation layer, a second encapsulation layer, and a third encapsulation layer stacked in sequence in a direction away from the first stretchable substrate, wherein materials of the first encapsulation layer and the third encapsulation layer are inorganic materials, and a material of the second encapsulation layer is an organic material; and
the one or more second groove structures are disposed on a surface of the third encapsulation layer away from the first stretchable substrate; a distance between a surface of the second groove structure close to the first stretchable substrate and a surface of the third encapsulation layer close to the first stretchable substrate is greater than or equal to 600 nanometers.

14. The display panel according to claim 1, further comprising a fixed film layer; wherein
the fixed film layer is disposed in the island-shaped display regions and between the first adhesive layer and the first stretchable substrate, and the first adhesive layer is configured to connect the fixed film layer and the first flexible substrate.

15. The display panel according to claim 14, wherein in a case that a side of the first flexible substrate close to the first stretchable substrate is provided with one or more first groove structures, the fixed film layer comprises a fixed layer, and one or more protruding structures disposed on a side of the fixed layer away from the first stretchable substrate and corresponding to the one or more first groove structures; and
an orthographic projection of each of the protruding structures on the first stretchable substrate is within an orthographic projection of a corresponding first groove structure on the first stretchable substrate.

16. The display panel according to claim 15, wherein a height of each of the protruding structures is less than a depth of the corresponding first groove structure; and a thickness of the fixed layer is greater than or equal to 1 micron.

17. The display panel according to claim 2, wherein the display layer comprises a barrier layer, a buffer layer, an active layer, a gate insulating layer, a gate layer, an interlayer dielectric layer, a source-drain electrode layer, a planarization layer, an anode layer, a pixel defining layer, a light-emitting layer, and a cathode layer; wherein
the active layer comprises an active pattern, wherein the active pattern comprises a source region, a drain region, and a channel region;
the source-drain electrode layer comprises a source electrode and a drain electrode, wherein the source electrode is connected to the source region through a first via hole in the interlayer dielectric layer and the gate insulating layer, and the drain electrode is connected to the drain region through a second via hole in the interlayer dielectric layer and the gate insulating layer; and
the gate layer comprises a gate pattern, and the channel region is an overlapping region of an orthographic projection of the gate pattern on the first stretchable substrate and an orthographic projection of the active pattern on the first stretchable substrate.

18. The display panel according to claim 17, wherein a plurality of signal lines in the display substrate are disposed in the source-drain electrode layer; and a second flexible film layer in the display substrate and the planarization layer are disposed in a same layer.

19. A method for manufacturing a display panel, comprising:
forming a display substrate on a glass substrate, wherein the display substrate comprises a plurality of display units;
forming a temporary adhesive material and a protective film on a side of the display substrate away from the glass base;
removing the glass substrate, and adhering a first stretchable substrate to a side of the display substrate away from the protective film using a first adhesive layer; and
removing the temporary adhesive material and the protective film, and adhering the second stretchable substrate to a side of the display substrate away from the first stretchable substrate using a second adhesive layer;
wherein the first stretchable substrate comprises a plurality of island-shaped display regions, a stretchable region connecting adjacent island-shaped display regions, and a hollow-out region between one of the island-shaped display regions and the stretchable region; a plurality of display units disposed in the island-shaped display regions; an orthographic projection of the first adhesive layer on the first stretchable substrate is within orthographic projections of the display units on the first stretchable substrate, and an orthographic projection of the second adhesive layer on the first stretchable substrate is within the orthographic projections of the display units on the first stretchable substrate.

20. The method according to claim 19, wherein the forming the display substrate on the glass substrate comprises:
forming one or more protrusions on the glass substrate, and forming a first flexible substrate film, a display film, and an encapsulation film on a side of the protrusions away from the glass substrate; and
obtaining a first flexible substrate, a display layer, and an encapsulation film layer disposed in the island-shaped display regions, and obtaining a second flexible substrate, a first flexible film layer, and a second flexible film layer disposed in the stretchable region by etching the first flexible substrate film, the display film, and the encapsulation film to remove the first flexible substrate film, the display film, and the encapsulation film disposed in the hollow-out region; and
the removing the glass substrate, and adhering the first stretchable substrate to the side of the display substrate away from the protective film using the first adhesive layer comprises:
removing the glass substrate and the protrusions on the glass substrate, so that a side of the first flexible substrate away from the display layer is provided with one or more first groove structures, and
adhering the first stretchable substrate to a side of the display substrate away from the protective film using a first adhesive layer, wherein a portion of the first adhesive layer is disposed in the first groove structures, a portion of a surface of the first adhesive layer close to the first flexible substrate is adhered to an inner wall of the first groove structures, and a surface of the first adhesive layer close to the first stretchable substrate is adhered to the first stretchable substrate.

21. A display device, comprising a power supply component and the display panel as defined in claim 1; wherein
the power supply component is connected to the display panel, and is configured to supply power to the display panel.
